(19) United States
(12) Patent Application Publication
(10) Pub. No.: US 2025/0261418 A1
(43) Pub. Date: Aug. 14, 2025

(54) SEMICONDUCTOR DEVICE AND METHOD OF MANUFACTURING THE SAME

(71) Applicant: FUJI ELECTRIC CO., LTD., Kawasaki-shi (JP)

(72) Inventor: Taichi KARINO, Matsumoto-city (JP)

(73) Assignee: FUJI ELECTRIC CO., LTD., Kawasaki-shi (JP)

(21) Appl. No.: 18/999,966

(22) Filed: Dec. 23, 2024

(30) Foreign Application Priority Data
Feb. 8, 2024 (JP) 2024-017742

(51) Int. Cl. H10D 62/10; H01L 21/225; H01L 23/528; H10D 62/13; H10D 84/01; H10D 84/83

(52) U.S. Cl. CPC H10D 62/127; H01L 21/225; H01L 23/5286; H10D 62/153; H10D 84/0133; H10D 84/83125; H10D 84/835

(57) ABSTRACT

A method of manufacturing a semiconductor device includes: forming a well region of a second conductivity-type on a top surface side of a semiconductor base-body of a first conductivity-type; forming a plurality of channel formation regions of the first conductivity-type on a top surface side of the well region; forming a plurality of drift regions on the top surface side of the well region alternately with the channel formation regions; forming a plurality of gate electrodes on top surface sides of the respective channel formation regions with a gate insulating film interposed; and forming a wiring layer arranged over the well region, wherein forming the well region including: forming a plurality of first ion implantation regions formed into slits and having different widths, and forming a second ion implantation region at a position overlapping with the wiring layer on an end part side of the first ion implantation regions having a relatively narrow width; and forming the well region by annealing.

### CROSS-REFERENCE TO RELATED APPLICATION

This application claims benefit of priority under 35 USC 119 based on Japanese Patent Application No. 2024-017742 filed on Feb. 8, 2024, the entire contents of which are incorporated by reference herein.

### BACKGROUND OF THE INVENTION

### 1. Field of the Invention

The present disclosure relates to semiconductor devices and methods of manufacturing the same.

### 2. Description of the Related Art

JP2015-233056A discloses a lateral MOSFET in which source regions and drain regions are alternately arranged in a short-side direction (a gate-length direction) perpendicular to a longitudinal direction of gate electrodes.

Semiconductor devices such as a lateral MOSFET include an n-type well region implementing a voltage blocking structure on a top surface side of a p-type semiconductor base-body.

Upon the formation of the n-type well region, n-type impurity ions are implanted into plural slits in order to adjust an impurity concentration in the n-type well region, and then subject the implanted n-type impurity ions to annealing to be activated so as to form the single n-type well region.

However, the provision of the thin slit-shaped parts in the ion-implanted region impedes a sufficient diffusion of the implanted n-type impurity ions in the lateral direction, which may cause a region having a locally low impurity concentration in the n-type well region. If a wiring layer overlaps with the region with the low impurity concentration, a channel may be formed on the surface of such a region, leading to a leakage path accordingly.

### SUMMARY OF THE INVENTION

In view of the foregoing problems, the present disclosure provides a semiconductor device having a configuration capable of avoiding a reduction in impurity concentration in an n-type well region provided immediately under a wiring layer and preventing a cause of a leakage path, and also provides a method of manufacturing the same.

An aspect of the present disclosure inheres in a semiconductor device including: A semiconductor device including: a semiconductor base-body of a first conductivity-type; a well region of a second conductivity-type provided on a top surface side of the semiconductor base-body; a plurality of channel formation regions of the first conductivity-type provided on a top surface side of the well region and extending parallel to each other in one direction in a planar view; a plurality of drift regions provided on the top surface side of the well region alternately with the channel formation regions and extending parallel to each other in the one direction; a plurality of carrier-supply regions of the second conductivity-type provided on top surface sides of the respective channel formation regions; a plurality of carrier-reception regions of the second conductivity-type provided on top surface sides of the respective drift regions; a plurality of gate electrodes provided on top surface sides of the respective channel formation regions with a gate insulating film interposed at positions between the carrier-supply regions and the well region, and extending parallel to each other in the one direction; and a wiring layer arranged over the well region on an end part side of the channel formation regions and the drift regions in the one direction to extend in a direction perpendicular to the one direction, wherein an impurity concentration of the well region at a position located on the end part side of the channel formation regions interposed between the drift regions next to each other and overlapping with the wiring layer is greater than or equal to that of the well region at a position on the end part side of the drift regions and overlapping with the wiring layer.

Another aspect of the present disclosure inheres in a method of manufacturing the above semiconductor device, the method includes forming the well region including: implanting impurity ions of the second conductivity-type to form a plurality of first ion implantation regions formed into slits extending parallel to the one direction and having different widths, and form a second ion implantation region extending in the direction perpendicular to the one direction at a position overlapping with the wiring layer on an end part side of one of the first ion implantation regions having a relatively narrow width; and diffusing the impurity ions implanted to the first ion implantation regions and the second ion implantation region in a lateral direction by annealing so as to form the well region.

### BRIEF DESCRIPTION OF THE DRAWINGS

FIG. 1 is a cross-sectional view illustrating a semiconductor device according to a first embodiment;

FIG. 2 is a plan view illustrating the semiconductor device according to the first embodiment;

FIG. 3 is a plan view illustrating the semiconductor device according to the first embodiment;

FIG. 4 is a cross-sectional view taken along line A-A′ in FIG. 2 and FIG. 3;

FIG. 5 is a cross-sectional view taken along line B-B′in FIG. 2 and FIG. 3;

FIG. 6 is a cross-sectional view for explaining a method of manufacturing the semiconductor device according to the first embodiment;

FIG. 7 is a cross-sectional view for explaining the method of manufacturing the semiconductor device according to the first embodiment;

FIG. 8A is a plan view for explaining the method of manufacturing the semiconductor device according to the first embodiment;

FIG. 8B is a plan view for explaining the method of manufacturing the semiconductor device according to the first embodiment;

FIG. 9 is a cross-sectional view taken along line A-A′ in FIG. 8A and FIG. 8B;

FIG. 10 is a cross-sectional view taken along line B-B′ in FIG. 8A and FIG. 8B;

FIG. 11 is a cross-sectional view continued from FIG. 6, for explaining the method of manufacturing the semiconductor device according to the first embodiment;

FIG. 12 is a cross-sectional view taken along line A-A′ in FIG. 8A and FIG. 8B at a phase corresponding to FIG. 11;

FIG. 13 is a cross-sectional view taken along line B-B′ in FIG. 8A and FIG. 8B at a phase corresponding to FIG. 11;

FIG. 14 is a cross-sectional view continued from FIG. 11, for explaining the method of manufacturing the semiconductor device according to the first embodiment;

FIG. 15 is a cross-sectional view continued from FIG. 14, for explaining the method of manufacturing the semiconductor device according to the first embodiment;

FIG. 16 is a cross-sectional view continued from FIG. 15, for explaining the method of manufacturing the semiconductor device according to the first embodiment;

FIG. 17 is a cross-sectional view illustrating a semiconductor device of a first comparative example;

FIG. 18 is a cross-sectional view for explaining a method of manufacturing the semiconductor device of the first comparative example;

FIG. 19 is a plan view for explaining a method of manufacturing a semiconductor device of a second comparative example;

FIG. 20 is a plan view for explaining a method of manufacturing a semiconductor device according to a second embodiment; and

FIG. 21 is a plan view for explaining a method of manufacturing a semiconductor device according to a third embodiment.

### DETAILED DESCRIPTION

With reference to the drawings, first to third embodiments of the present disclosure will be described below.

In the drawings, the same or similar elements are indicated by the same or similar reference numerals. The drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions. The first to third embodiments described below merely illustrate schematically devices and methods for specifying and giving shapes to the technical idea of the present disclosure, and the span of the technical idea is not limited to materials, shapes, structures, and relative positions of elements described herein.

In the specification, a “carrier-supply region” means a semiconductor region which supplies majority carriers as a main current. The carrier-supply region is assigned to a semiconductor region which will be a source region in a field-effect transistor (FET) or a static induction transistor (SIT), an emitter region in an insulated-gate bipolar transistor (IGBT), and an anode region in a diode, a static induction (SI) thyristor or a gate turn-off (GTO) thyristor. A “carrier-reception region” means a semiconductor region which receive the majority carriers as the main current. The carrier-reception region is assigned to a semiconductor region which will be the drain region in the FET or the SIT, the collector region in the IGBT, and the cathode region in the diode, SI thyristor or GTO thyristor.

In the specification, definitions of directions such as an up-and-down direction in the following description are merely definitions for convenience of understanding, and are not intended to limit the technical ideas of the present disclosure. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction.

In the specification, there is exemplified a case where a first conductivity-type is a p-type and a second conductivity-type is an n-type. However, the relationship of the conductivity-types may be inverted to set the first conductivity-type to the n-type and the second conductivity-type to the p-type. Further, a semiconductor region denoted by the symbol “n” or “p” attached with “+” indicates that such semiconductor region has a relatively high impurity concentration as compared to a semiconductor region denoted by the symbol “n” or “p” without “+”. A semiconductor region denoted by the symbol “n” or “p” attached with “−” indicates that such semiconductor region has a relatively low impurity concentration as compared to a semiconductor region denoted by the symbol “n” or “p” without “−”. However, even when the semiconductor regions are denoted by the same reference symbols “n” and “n”, it is not indicated that the semiconductor regions have exactly the same impurity concentration. Moreover, the members and the regions that are limited by adding “first conductivity-type” and “second conductivity-type” in the following description indicate the members and the regions formed of semiconductor materials without particular obvious limitations.

### FIRST EMBODIMENT

### <Configuration of Semiconductor Device>

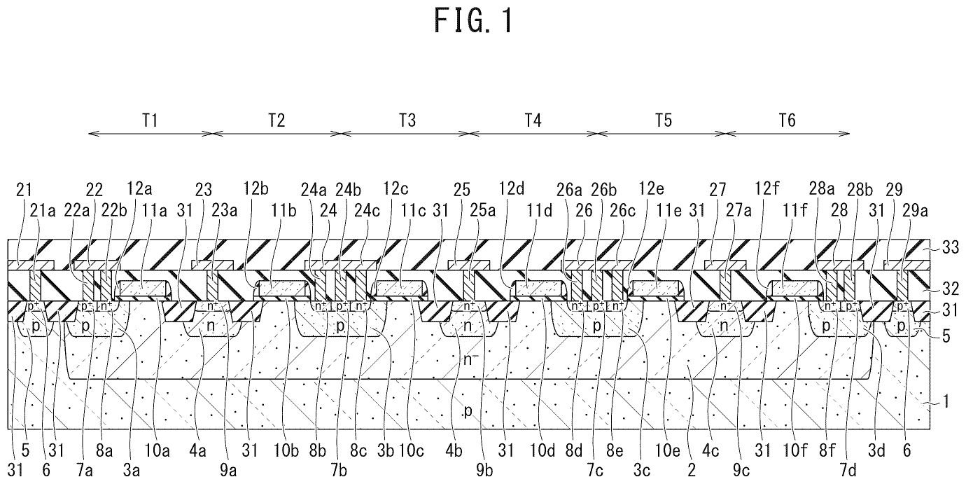

A semiconductor device according to a first embodiment is illustrated below with a lateral n-channel metal-oxide-semiconductor field-effect transistor (MOSFET). As illustrated in FIG. 1, the semiconductor device according to the first embodiment includes an array of plural transistor cells T1 to T6. While FIG. 1 illustrates the case of including the six transistor cells T1 to T6, the number of the transistor cells in array may be changed as appropriate. The semiconductor device according to the first embodiment has a breakdown voltage of about 60 volts or higher, for example.

The semiconductor device according to the first embodiment includes a semiconductor base-body 1 of a first conductivity-type (p-type). The semiconductor base-body 1 is a semiconductor substrate such as a silicon (Si) substrate, for example. The semiconductor base-body 1 may be a semiconductor substrate including silicon carbide (SiC), gallium nitride (GaN), gallium oxide (Ga₂O₃), gallium arsenide (GaAs), or diamond (C), for example. Alternatively, the semiconductor base-body 1 may be implemented by a semiconductor region (a semiconductor layer) of p-type provided on the top surface side of a semiconductor substrate of p-type or n-type.

A well region (deep n-well: DNW) 2 of a second conductivity-type (n-type) is provided on the top surface side (at the upper part) of the semiconductor base-body 1. A plurality of channel formation regions (well regions) 3a to 3d of p-type are provided separately from each other on the top surface side (at the upper part) of the well region 2. A plurality of drift regions 4a to 4c of n-type having a higher impurity concentration than the well region 2 are provided separately from each other on the top surface side (at the upper part) of the well region 2. The drift regions 4a to 4c are arranged alternately with the channel formation regions 3a to 3d.

A contact region 7a of p⁺-type and a carrier-supply region (a source region) 8a of n⁺-type are provided on the top surface side (at the upper part) of the channel formation region 3a. The contact region 7a and the source region 8a are in contact with each other. The contact region 7a has a higher impurity concentration than the channel formation region 3a. The contact region 7a is connected to a source electrode 22 arranged on the top surface side of an interlayer insulating film 32 provided on the top surface side of the semiconductor base-body 1 through a via 22a penetrating the interlayer insulating film 32. The source region 8a is connected to the source electrode 22 through a via 22b penetrating the interlayer insulating film 32. The source electrode 22 is covered with a passivation insulating film 33 provided on the top surface side of the interlayer insulating film 32.

The interlayer insulating film 32 as used herein can be a non-doped silicon oxide film without containing phosphorus (P) or boron (B) (an SiO₂ film) which is referred to as a non-doped silicate glass (NSG) film. Other examples used as the interlayer insulating film 32 include a phosphosilicate glass film (a PSG film), a borosilicate glass film (a BSG film), a borophosphosilicate glass film (a BPSG film), a silicon nitride (Si₃N₄) film, and a stacked layer including the above films stacked on one another. The passivation insulating film 33 as used herein can be a film including resin such as polyimide.

A carrier-reception region (a drain region) 9a of n⁺-type having a higher impurity concentration than the drift region 4a is provided on the top surface side (at the upper part) of the drift region 4a. The drain region 9a is connected to a drain electrode 23 provided on the top surface side of the interlayer insulating film 32 through a via 23a penetrating the interlayer insulating film 32. An insulating film (an element-separation insulating film) 31 is provided on both sides of the respective side surfaces of the drift region 4a and the drain region 9a.

The element-separation insulating film 31 is an oxide film such as a local insulating film (a LOCOS film) selectively (locally) formed by local oxidation of silicon (LOCOS).

A gate electrode 11a is provided on the top surface sides of the channel formation region 3a and the well region 2 with the gate insulating film 10a interposed at a position between the source region 8a and the drain region 9a. A side-wall insulating film 12a is provided to cover the side surfaces on both sides of the gate electrode 11a.

The gate insulating film 10a as used herein can be a silicon oxide (SiO₂) film, or can be any of a silicon oxynitride (SiON) film, a strontium oxide (SrO) film, a silicon nitride (Si₃N₄) film, an aluminum oxide (Al₂O₃) film, a magnesium oxide (MgO) film, an yttrium oxide (Y₂O₃) film, a hafnium oxide (HfO₂) film, a zirconium oxide (ZrO₂) film, a tantalum oxide (Ta₂O₅) film, or a bismuth oxide (Bi₂O₃) film, or a composite film including some of the above films stacked on one another. The gate electrode 11a may be a polysilicon layer (a doped polysilicon layer) heavily doped with p-type impurities such as boron (B) or n-type impurities such as phosphorus (P), or may be a layer including refractory metal.

A carrier-supply region (a source region) 8b of n⁺-type, a contact region 7b of p⁺-type, and a carrier-supply region (a source region) 8c of n⁺-type are provided on the top surface side (at the upper part) of the channel formation region 3b. The source region 8b and the contact region 7b are in contact with each other. The contact region 7b and the source region 8c are in contact with each other. The source region 8b is connected to a source electrode 24 provided on the top surface side of the interlayer insulating film 32 through a via 24a penetrating the interlayer insulating film 32. The contact region 7b has a higher impurity concentration than the channel formation region 3b. The contact region 7b is connected to the source electrode 24 through a via 24b penetrating the interlayer insulating film 32. The source region 8c is connected to the source electrode 24 through a via 24c penetrating the interlayer insulating film 32. The source electrode 24 is covered with the passivation insulating film 33.

A gate electrode 11b is provided on the top surface sides of the channel formation region 3b and the well region 2 with the gate insulating film 10b interposed at a position between the drain region 9a and the source region 8b. A side-wall insulating film 12b is provided to cover the side surfaces on both sides of the gate electrode 11b.

A carrier-reception region (a drain region) 9b of n⁺-type having a higher impurity concentration than the drift region 4b is provided on the top surface side (at the upper part) of the drift region 4b. The drain region 9b is connected to a drain electrode 25 provided on the top surface side of the interlayer insulating film 32 through a via 25a penetrating the interlayer insulating film 32. The element-separation insulating film 31 is provided on both sides of the respective side surfaces of the drift region 4b and the drain region 9b.

A gate electrode 11c is provided on the top surface sides of the channel formation region 3b and the well region 2 with the gate insulating film 10c interposed at a position between the source region 8c and the drain region 9b. A side-wall insulating film 12c is provided to cover the side surfaces on both sides of the gate electrode 11c.

A carrier-supply region (a source region) 8d of n⁺-type, a contact region 7c of p⁺-type, and a carrier-supply region (a source region) 8e of n⁺-type are provided on the top surface side (at the upper part) of the channel formation region 3c. The source region 8d and the contact region 7c are in contact with each other. The contact region 7c and the source region 8e are in contact with each other. The source region 8d is connected to a source electrode 26 provided on the top surface side of the interlayer insulating film 32 through a via 26a penetrating the interlayer insulating film 32. The contact region 7c has a higher impurity concentration than the channel formation region 3c. The contact region 7c is connected to the source electrode 26 through a via 26b penetrating the interlayer insulating film 32. The source region 8e is connected to the source electrode 26 through a via 26c penetrating the interlayer insulating film 32. The source electrode 26 is covered with the passivation insulating film 33.

A gate electrode 11d is provided on the top surface sides of the channel formation region 3c and the well region 2 with the gate insulating film 10d interposed at a position between the drain region 9b and the source region 8d. A side-wall insulating film 12d is provided to cover the side surfaces on both sides of the gate electrode 11d.

A carrier-reception region (a drain region) 9c of n⁺-type having a higher impurity concentration than the drift region 4c is provided on the top surface side (at the upper part) of the drift region 4c. The drain region 9c is connected to a drain electrode 27 provided on the top surface side of the interlayer insulating film 32 through a via 27a penetrating the interlayer insulating film 32. The element-separation insulating film 31 is provided on both sides of the respective side surfaces of the drift region 4c and the drain region 9c.

A gate electrode 11e is provided on the top surface sides of the channel formation region 3c and the well region 2 with the gate insulating film 10e interposed at a position between the source region 8e and the drain region 9c. A side-wall insulating film 12e is provided to cover the side surfaces on both sides of the gate electrode 11e.

A carrier-supply region (a source region) 8f of n⁺-type and a contact region 7d of p⁺-type are provided on the top surface side (at the upper part) of the channel formation region 3d. The source region 8f and the contact region 7d are in contact with each other. The source region 8f is connected to a source electrode 28 provided on the top surface side of the interlayer insulating film 32 through a via 28a penetrating the interlayer insulating film 32. The contact region 7d has a higher impurity concentration than the channel formation region 3d. The contact region 7d is connected to the source electrode 28 through a via 28b penetrating the interlayer insulating film 32. The source electrode 28 is covered with the passivation insulating film 33.

A gate electrode 11f is provided on the top surface sides of the channel formation region 3d and the well region 2 with the gate insulating film 10f interposed at a position between the drain region 9c and the source region 8f. A side-wall insulating film 12f is provided to cover the side surfaces on both sides of the gate electrode 11f.

The transistor cell T1 includes the contact region 7a, the source region 8a, the drain region 9a, and the gate electrode 11a. The transistor cell T2 has a linearly symmetric structure with respect to the transistor cell T1 about the drain region 9a. The transistor cell T2 includes the contact region 7b, the source region 8b, the drain region 9b, and the gate electrode 11b. The drain region 9a is commonly used in the respective transistor cells T1 and T2.

The transistor cell T3 has a linearly symmetric structure with respect to the transistor cell T2 about the contact region 7b. The transistor cell T3 includes the contact region 7b, the source region 8c, the drain region 9b, and the gate electrode 11c. The contact region 7b is commonly used in the respective transistor cells T2 and T3.

The transistor cell T4 has a linearly symmetric structure with respect to the transistor cell T3 about the drain region 9b. The transistor cell T4 includes the contact region 7c, the source region 8d, the drain region 9b, and the gate electrode 11d. The drain region 9b is commonly used in the respective transistor cells T3 and T4.

The transistor cell T5 has a linearly symmetric structure with respect to the transistor cell T4 about the contact region 7c. The transistor cell T5 includes the contact region 7c, the source region 8e, the drain region 9c, and the gate electrode 11d. The contact region 7c is commonly used in the respective transistor cells T4 and T5.

The transistor cell T6 has a linearly symmetric structure with respect to the transistor cell T5 about the drain region 9c. The transistor cell T6 includes the contact region 7d, the source region 8f, the drain region 9c, and the gate electrode 11f. The drain region 9c is commonly used in the respective transistor cells T5 and T6.

A well region 5 of p-type having a higher impurity concentration than the semiconductor base-body 1 is provided on the top surface side (at the upper part) of the semiconductor base-body 1 on the outside of the well region 2. A contact region 6 of p⁺-type having a higher impurity concentration than the well region 5 is provided on the top surface side (at the upper side) of the well region 5. The contact region 6 is connected to substrate contact electrodes 21 and 29 provided on the top surface side of the interlayer insulating film 32 through vias 21a and 29a penetrating the interlayer insulating film 32. The substrate contact electrodes 21 and 29 can be connected to each other on the frontward and backward sides of FIG. 1. The substrate contact electrodes 21 and 29 are covered with the passivation insulating film 33. The element-separation insulating film 31 is provided on both sides of the respective side surfaces of the well region 5 and the contact region 6.

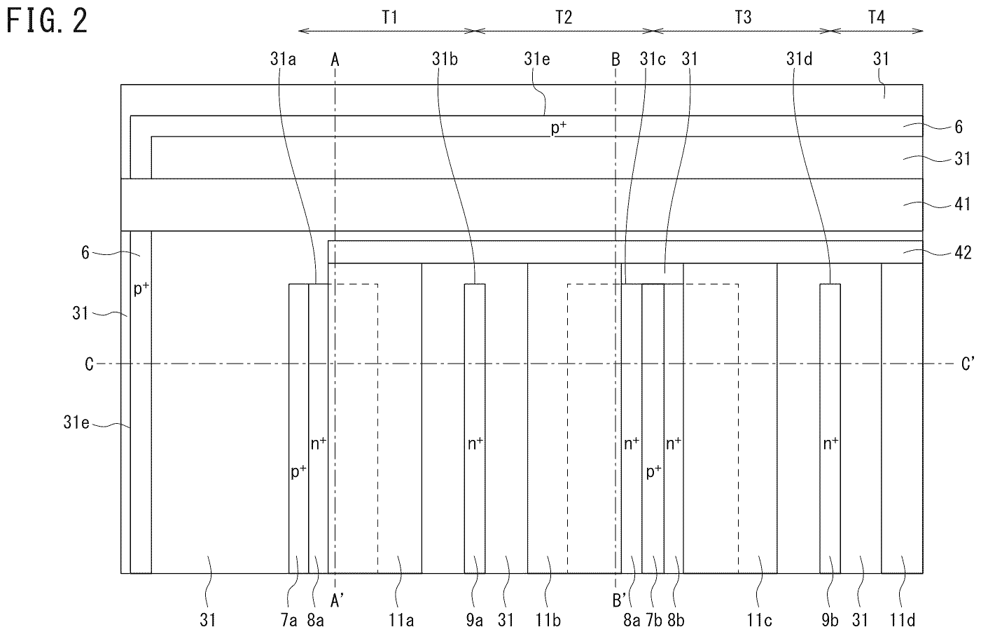

FIG. 2 is a plan view illustrating a part of the semiconductor device according to the first embodiment illustrated in FIG. 1. The cross-section taken along line C-C′ in FIG. 2 corresponds to the region including the transistor cells TI to T4 on the left side of the cross section in FIG. 1. FIG. 2 omits the illustration of the interlayer insulating film 32, the passivation insulating film 33, the vias 21a, 22a, 22b, 23a, 24a to 24c, and 25a, the substrate contact electrode 21, the source electrodes 22 and 24, and the drain electrodes 23 and 25 illustrated in FIG. 1.

As illustrated in FIG. 2, the gate electrodes 11a to 11d each have a stripe-shaped planar pattern to extend parallel to each other in one direction (in the upper-lower direction in FIG. 2). A gate wiring layer 42 is arranged above the respective end parts of the gate electrodes 11a to 11d. The gate wiring layer 42 has a stripe-shaped planar pattern extending in the direction perpendicular to the extending direction of the gate electrodes 11a to 11d (in the right-left direction in FIG. 2). The gate wiring layer 42 is electrically connected to the gate electrodes 11a to 11d. The gate electrodes 11e and 11f illustrated in FIG. 1 also each have a strip-shaped planar pattern to extend parallel to each other in one direction (in the upper-lower direction in FIG. 2) in the same manner as the gate electrodes 11a to 11d, and are electrically connected to the gate wiring layer 42.

A wiring layer 41 is provided separately from the gate wiring layer 42. The wiring layer 41 has a stripe-shaped planar pattern extending parallel to the extending direction of the gate wiring layer 42 (in the right-left direction in FIG. 2). The wiring layer 41 may be a source wiring layer connected to the respective source electrodes 22, 24, 26, and 28 illustrated in FIG. 1, for example. Alternately, the wiring layer 41 may be a drain wiring layer connected to the respective drain electrodes 23, 25, and 27. The wiring layer 41 may be another layer to which a potential is applied, other than the source wiring layer or the drain wiring layer.

The element-separation insulating film 31 is provided with openings 31a to 31e. FIG. 2 illustrates the openings 31a and 31c of the element-separation insulating film 31 and also schematically indicates, by the broken lines, the parts of the openings 31a and 31c hidden immediately under the gate electrodes 11a to 11c. The contact region 7a and the source region 8a are exposed to the opening 31a of the element-separation insulating film 31. The drain region 9a is exposed to the opening 31b of the element-separation insulating film 31. The contact region 7b and the source regions 8a and 8c are exposed to the opening 31c of the element-separation insulating film 31. The drain region 9b is exposed to the opening 31d of the element-separation insulating film 31. The contact region 6 is exposed to the opening 31e of the element-separation insulating film 31.

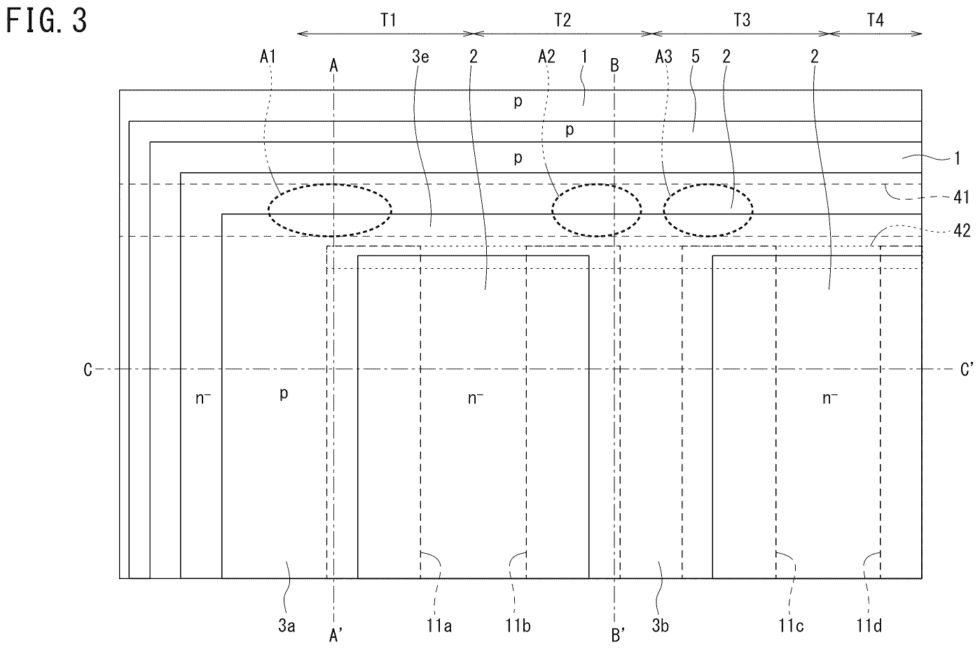

FIG. 3 is a plan view illustrating the semiconductor device according to the first embodiment at a region common to that illustrated in FIG. 2. FIG. 3 schematically indicates, by the solid lines, the n″-type well region 2, the p-type channel formation regions 3a and 3b, the p-type connection region 3e, and the p-type well region 5 provided in the p-type semiconductor base-body 1.

As illustrated in FIG. 3, the well region 2 has a substantially rectangular planar pattern. The channel formation regions 3a and 3b are provided inside the well region 2. The channel formation regions 3a and 3b each have a stripe-shaped planar pattern extending in the extending direction of the gate electrodes 11a to 11d (in the upper-lower direction in FIG. 3). The connection region 3e is connected to the end parts of the channel formation regions 3a and 3b in the extending direction. The connection region 3e has a stripe-shaped planar pattern extending in the direction perpendicular to the extending direction of the gate electrodes 11a to 11d (in the right-left direction in FIG. 3). The channel formation regions 3c and 3d illustrated in FIG. 1 also each have a stripe-shaped planar pattern extending in the extending direction of the gate electrodes 11a to 11d (in the upper-lower direction in FIG. 3), and are connected to the connection region 3e, as in the case of the channel formation regions 3a and 3b. The well region 5 has a loop-shaped planar pattern surrounding the circumference of the well region 2.

Although not illustrated in FIG. 3, the drift regions 4a to 4c illustrated in FIG. 1 each have a stripe-shaped planar pattern extending in the extending direction of the gate electrodes 11a to 11d (in the upper-lower direction in FIG. 3). The end parts of the drift regions 4a to 4c are located inside the well region 2.

FIG. 3 illustrates, as a region A1 indicated by the broken line, a position of the end part of the well region 2 overlapping with the wiring layer 41 on the end part side of the gate electrode 11a and the channel formation region 3a in the extending direction. FIG. 3 also illustrates, as a region A2 indicated by the broken line, a position of the end part of the well region 2 overlapping with the wiring layer 41 on the end part side of the gate electrode 11b and the channel formation region 3b in the extending direction. FIG. 3 also illustrates, as a region A3 indicated by the broken line, a position of the end part of the well region 2 overlapping with the wiring layer 41 on the end part side of the gate electrode 11c and the channel formation region 3b in the extending direction.

In the semiconductor device according to the first embodiment, the impurity concentration of the well region 2 at the positions corresponding to the regions A2 and A3 indicated by the broken lines is higher than or equal to that of the well region 2 at the position overlapping with the wiring layer 41 other than the regions A2 and A3. For example, the impurity concentration of the well region 2 at the positions corresponding to the regions A2 and A3 is higher than or equal to that of the well region 2 at the position corresponding to the region A1. In addition, the impurity concentration of the well region 2 at the positions corresponding to the regions A2 and A3 is higher than or equal to that of the well region 2 at the position overlapping with the wiring layer 41 on the end part side of the drift regions 4a to 4c in the extending direction.

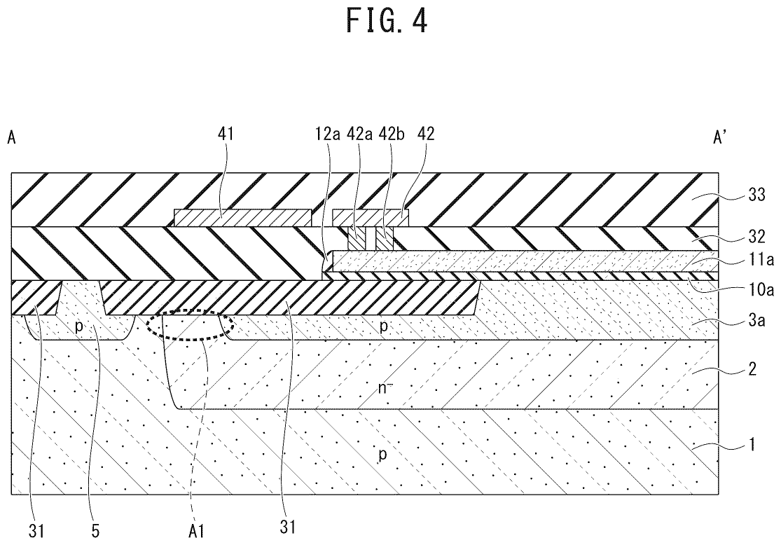

FIG. 4 is a cross-sectional view taken along taken along line A-A′ passing through the gate electrode 11a illustrated in FIG. 2 and FIG. 3. As illustrated in FIG. 3 and FIG. 4, the end part of the channel formation region 3a is located on the outside of the end part of the gate electrode 11a in the extending direction of the gate electrode 11a. The end part of the well region 2 is located on the outside of the end part of the channel formation region 3a so as to overlap with the wiring layer 41. The element-separation insulating film 31 is provided on the top surface side of the respective end parts of the channel formation region 3a and the well region 2. The region A1 indicated by the broken line surrounds the surface of the end part of the well region 2.

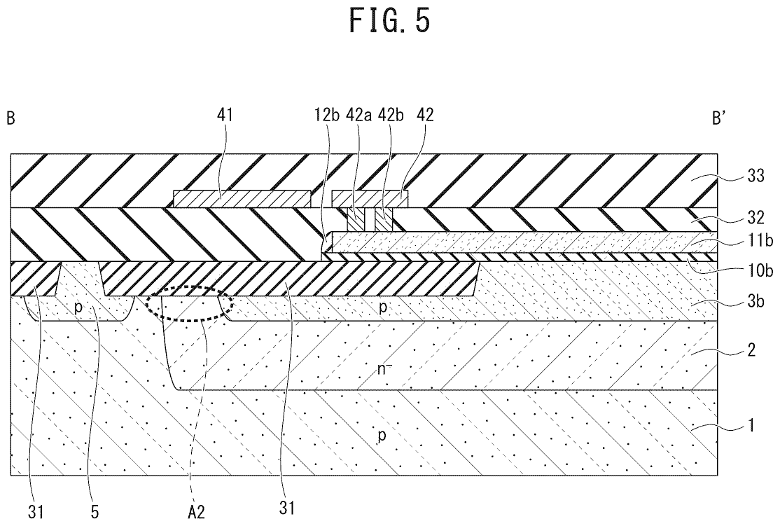

FIG. 5 is a cross-sectional view taken along taken along line B-B′ passing through the gate electrode 11b illustrated in FIG. 2 and FIG. 3. As illustrated in FIG. 3 and FIG. 5, the end part of the channel formation region 3b is located on the outside of the end part of the gate electrode 11b in the extending direction of the gate electrode 11b. The end part of the well region 2 is located on the outside of the end part of the channel formation region 3b so as to overlap with the wiring layer 41. The element-separation insulating film 31 is provided on the top surface side of the respective end parts of the channel formation region 3b and the well region 2. The region A2 indicated by the broken line surrounds the surface of the end part of the well region 2.

The semiconductor device according to the first embodiment has the configuration in which the impurity concentration of the well region 2 at the positions corresponding to the regions A2 and A3 indicated by the broken lines in FIG. 3 to FIG. 5 is regulated to be higher than or equal to that of the well region 2 at the position overlapping with the wiring layer 41 other than the regions A2 and A3. This configuration can avoid a formation of a channel on the surface of the well region 2 at the positions corresponding to the regions A2 and A3 indicated by the broken lines if a potential is applied to the wiring layer 41, so as to prevent a cause of a leakage path.

### <Method of Manufacturing Semiconductor Device>

An example of a method of manufacturing the semiconductor device according to the first embodiment is described below. The explanations for the manufacturing method according to the present embodiment are made below while focusing on the cross section of the semiconductor device illustrated in FIG. 1. It should be understood that the method of manufacturing the semiconductor device described below is an example, and the semiconductor device can be manufactured by various methods not disclosed herein including modified examples within the scope of the appended claims.

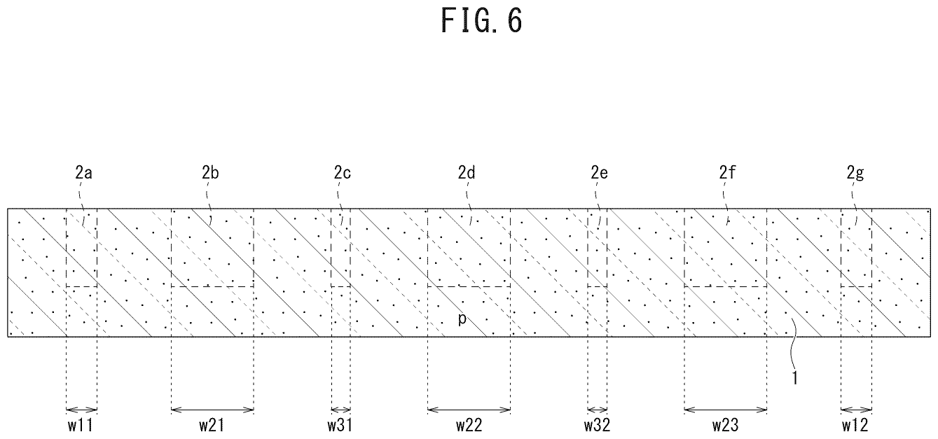

First, the p-type semiconductor base-body 1 (refer to FIG. 6) is prepared. A photoresist film is applied to the top surface of the semiconductor base-body 1, and is delineated by photolithography. Using the delineated photoresist film as a mask for ion implantation, n-type impurity ions such as phosphorus (P) are implanted so as to form the n-type well region 2. The photoresist film is then removed.

Next, a photoresist film is applied to the top surface of the semiconductor base-body 1, and is delineated by photolithography. Using the delineated photoresist film as a mask for ion implantation, p-type impurity ions such as boron (B) are implanted so as to form the p-type channel formation regions 3a to 3d and the p-type well region 5. The photoresist film is then removed.

Next, a photoresist film is applied to the top surface of the semiconductor base-body 1, and is delineated by photolithography. Using the delineated photoresist film as a mask for ion implantation, p-type impurity ions such as phosphorus (P) are implanted so as to form the n-type drift regions 4a to 4c. The photoresist film is then removed. The order of executing the ion implantation for forming the well region 2, the ion implantation for forming the p-type channel formation regions 3a to 3d and the p-type well region 5, and the ion implantation for forming the n-type drift regions 4a to 4c is not limited to the case described above, and may be changed as appropriate.

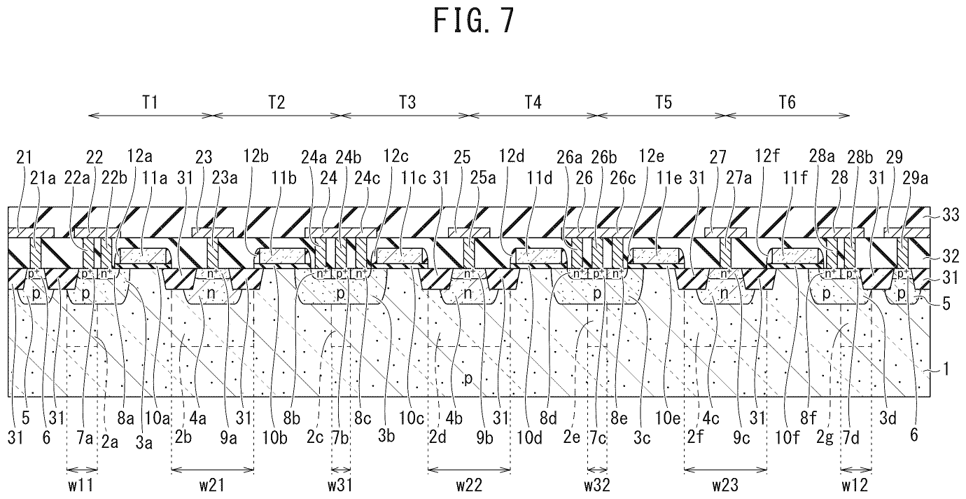

FIG. 6 is a cross-sectional view illustrating regions (ion implantation regions) 2a to 2g, indicated by the broken lines, to which the n-type impurity ions for forming the n-type well region 2 are implanted. FIG. 7 is a cross-sectional view schematically illustrating, instead of the n-type well region 2, the ion implantation regions 2a to 2g illustrated in FIG. 6 superposed on the semiconductor device according to the first embodiment illustrated in FIG. 1. For example, a single ion implantation region is formed for the provision of the well region 2 until the breakdown voltage reaches about 50 volts, while a plurality of ion implantation regions of n-type impurity ions for the provision of the well region 2 are formed into a slit state when the breakdown voltage is about 60 volts or higher in order to further decrease the impurity concentration of the well region 2. The implanted n-type impurity ions are then diffused in the lateral direction by annealing, so as to form the single well region 2.

As illustrated in FIG. 6 and FIG. 7, the ion implantation region 2a is formed to have a width w11 at a position overlapping with the channel formation region 3a. The ion implantation region 2b is formed to have a width w21 wider than the width w11 at a position overlapping with the drift region 4a. The ion implantation region 2c is formed to have a width w31 narrower than the widths w11 and w21 at a position overlapping with the channel formation region 3b. The ion implantation region 2d is formed to have a width w22 substantially equal to the width w21 at a position overlapping with the drift region 4b. The ion implantation region 2e is formed to have a width w32 substantially equal to the width w31 at a position overlapping with the channel formation region 3c. The ion implantation region 2f is formed to have a width w23 substantially equal to the widths w21 and w22 at a position overlapping with the drift region 4c. The ion implantation region 2g is formed to have a width w12 substantially equal to the width w11 at a position overlapping with the channel formation region 3d.

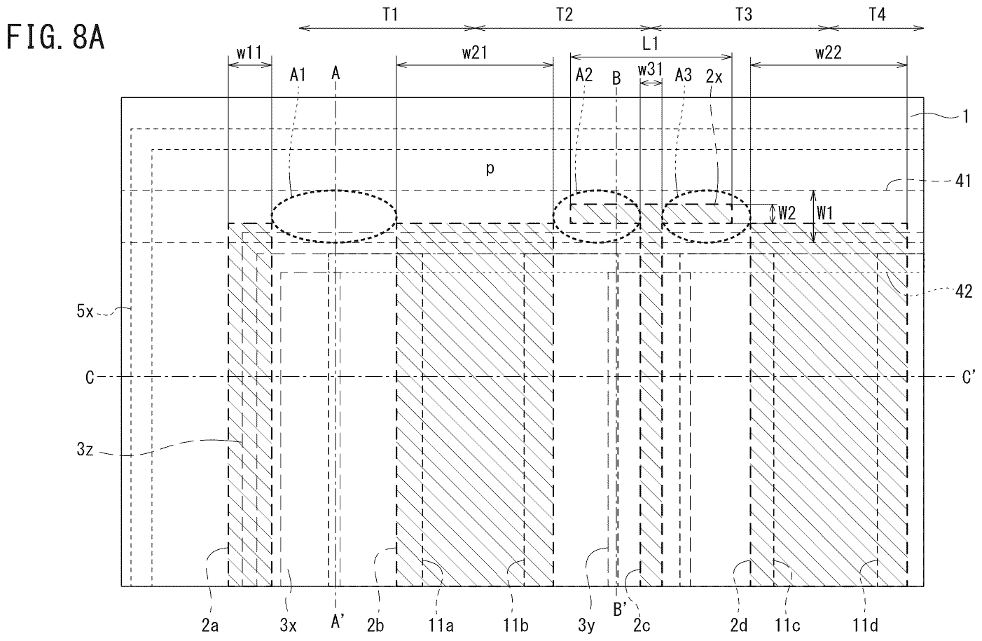

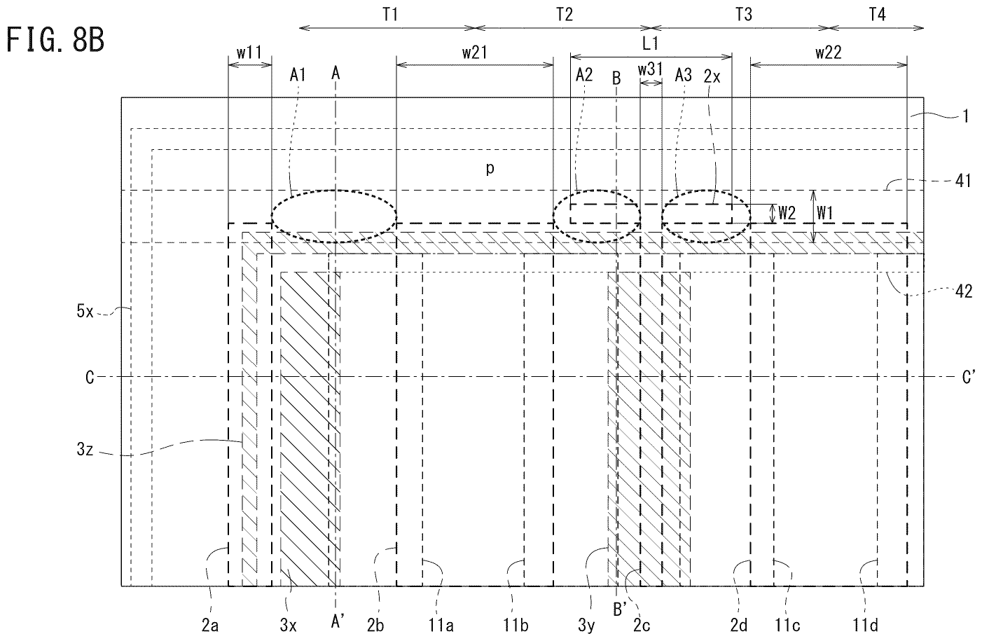

FIG. 8A is a plan view, at the phase corresponding to FIG. 6, schematically illustrating the ion implantation regions 2a to 2d and 2x surrounded by the broken lines and hatched by the right-downward oblique lines. FIG. 8A also schematically indicates, by the broken lines, ion implantation regions 3x to 3z for forming the p-type channel formation regions 3a and 3b and the p-type connection region 3e, and an ion implantation region 5x for forming the p-type well region 5. FIG. 8A also schematically indicates, by the broken lines, the gate electrodes 11a to 11d, the wiring layer 41, and the gate wiring layer 42 formed in the process described below.

The ion implantation regions 2a to 2d each have a stripe-shaped planar pattern extending in the extending direction of the gate electrodes 11a to 11d (in the upper-lower direction in FIG. 8A). The respective end parts of the ion implantation regions 2a to 2d overlap with the wiring layer 41.

The ion implantation region 2x is provided to overlap with the wiring layer 41 on the end part side of the ion implantation region 2c having the relatively narrow width w31 among the ion implantation regions 2a to 2d. The ion implantation region 2x has a stripe-shaped planar pattern extending in the direction perpendicular to the extending direction of the ion implantation region 2c (in the right-left direction in FIG. 8A). The ion implantation region 2x is connected to the end part of the ion implantation region 2c. The arrangement of the ion implantation region 2x and the ion implantation region 2c provides a T-shaped planar pattern. The ion implantation region 2x is separated from the other ion implantation regions 2b and 2d.

A length L1 of the ion implantation region 2x in the extending direction can be changed as appropriate within a range that leads the ion implantation region 2x to be separated from the ion implantation regions 2b and 2d. A width w2 of the ion implantation region 2x in the direction perpendicular to the extending direction can also be changed as appropriate. While FIG. 8A illustrates the case in which the width w2 of the ion implantation region 2x is narrower than the width w1 of the wiring layer 41, the width w2 of the ion implantation region 2x may be either equal to or wider than the width w1 of the wiring layer 41 instead. Further, FIG. 8A illustrates the case in which the entire ion implantation region 2x overlaps with the wiring layer 41, but the ion implantation region 2x may partly overlap with the wiring layer 41, while the other part of the ion implantation region 2x may be located on the outside of the wiring layer 41.

The other ion implantation regions 2e to 2g illustrated in FIG. 6 also have the stripe-shaped planar pattern extending in the extending direction of the gate electrodes 11a to 11d (in the upper-lower direction in FIG. 8A), as in the case of the ion implantation regions 2a to 2d. An ion implantation region similar to the ion implantation region 2x is connected to the end part of the ion implantation region 2e having the relatively narrow width w32. The ion implantation region 5x for forming the p-type well region 5, not hatched by the right-downward oblique lines, has a loop-shaped planar pattern.

While FIG. 8A illustrates the ion implantation regions 2a to 2d and 2x hatched by the right-downward oblique lines, FIG. 8B is a plan view schematically illustrating the ion implantation regions 3x to 3z, hatched by the right-downward oblique lines, for forming the p-type channel formation regions 3a and 3b and the p-type connection region 3e.

The ion implantation regions 3x and 3y each have a stripe-shaped planar pattern extending in the extending direction of the gate electrodes 11a to 11d (in the upper-lower direction in FIG. 8B). The ion implantation region 3z has a planar pattern including a stripe-shaped part extending in the extending direction of the ion implantation regions 3x and 3y (in the upper-lower direction in FIG. 8B) and a stripe-shaped part extending in the direction perpendicular to the extending direction of the ion implantation regions 3x and 3y (in the right-left direction in FIG. 8B).

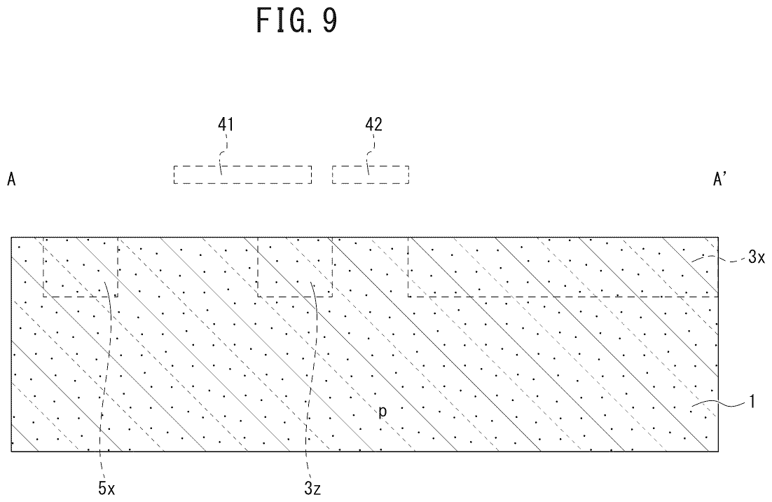

FIG. 9 is a cross-sectional view taken along line A-A′ in FIG. 8A and FIG. 8B. As illustrated in FIG. 9, the ion implantation regions 3x and 3z for forming the p-type channel formation region 3a and the p-type connection region 3e and the ion implantation region 5x for forming the p-type well region 5 are provided at the upper part of the semiconductor base-body 1.

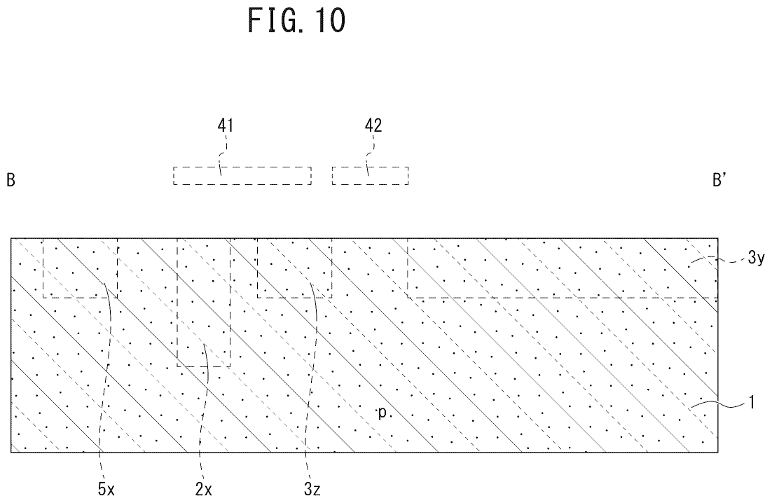

FIG. 10 is a cross-sectional view taken along line B-B′ in FIG. 8A and FIG. 8B. As illustrated in FIG. 10, the ion implantation regions 3y and 3z for forming the p-type channel formation region 3b and the p-type connection region 3e and the ion implantation region 5x for forming the p-type well region 5 are provided at the upper part of the semiconductor base-body 1. Further, the ion implantation region 2x for forming the n-type well region 2 is provided between the respective ion implantation regions 3y and 5x at the upper part of the semiconductor base-body 1.

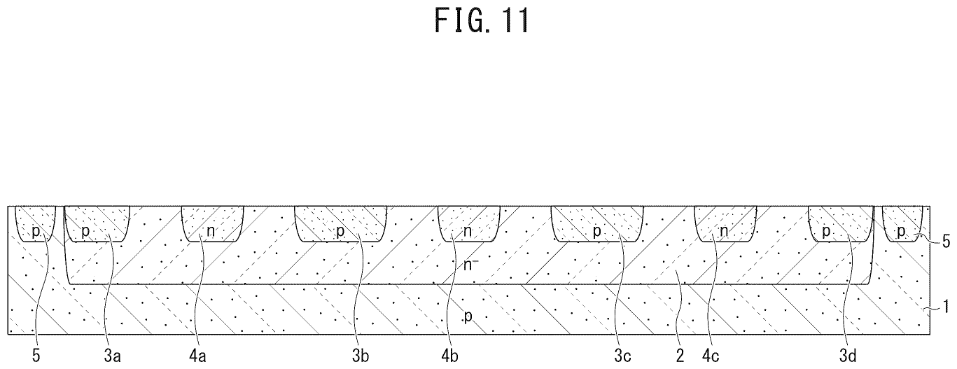

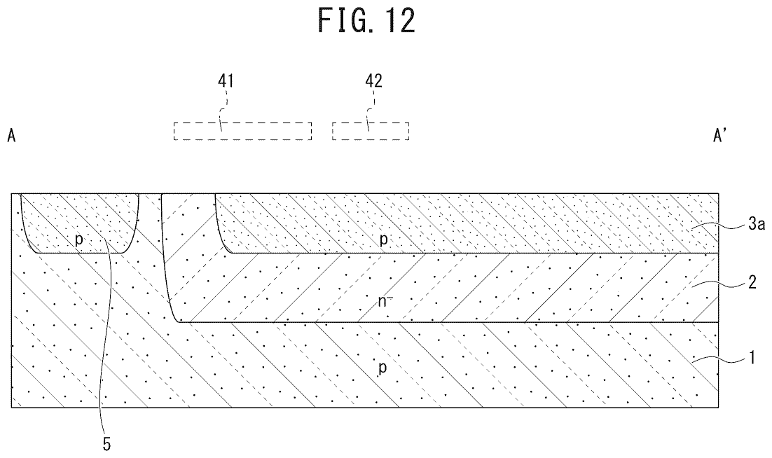

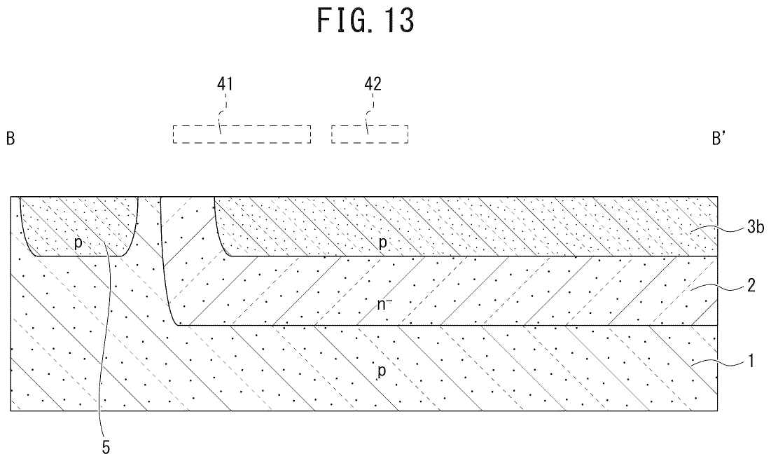

The p-type impurity ions and the n-type impurity ions implanted to the semiconductor base-body 1 are activated by annealing after the ion implantation for forming the well region 2, the ion implantation for forming the p-type channel formation regions 3a to 3d and the p-type well region 5, and the ion implantation for forming the n-type drift regions 4a to 4c. This step diffuses the n-type impurity ions in the ion implantation regions 2a to 2g in the lateral direction, so as to form the single n-type well region 2 on the top surface side of the semiconductor base-body 1, as illustrated in FIG. 11. In addition, the p-type channel formation regions 3a to 3d and the n-type drift regions 4a to 4c are also formed on the top surface side of the semiconductor base-body 1. The p-type well region 5 is also formed on the outside of the well region 2 on the top surface side of the semiconductor base-body 1. FIG. 12 is a cross-sectional view, at the phase corresponding to FIG. 11, taken along line A-A′ in FIG. 8A and FIG. 8B. FIG. 13 is a cross-sectional view, at the phase corresponding to FIG. 11, taken along line B-B′in FIG. 8A and FIG. 8B.

The annealing for forming the well region 2, the annealing for forming the channel formation regions 3a to 3d and the well region 5, and the annealing for forming the drift regions 4a to 4c are not necessarily executed collectively, but may be executed independently of each other upon each ion implantation.

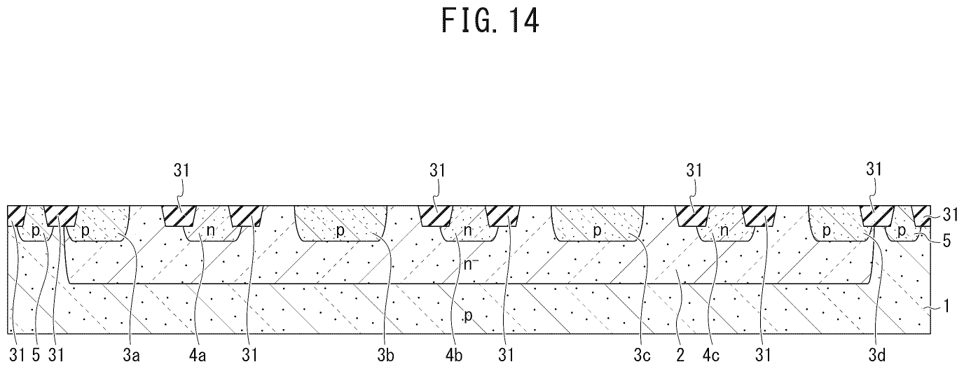

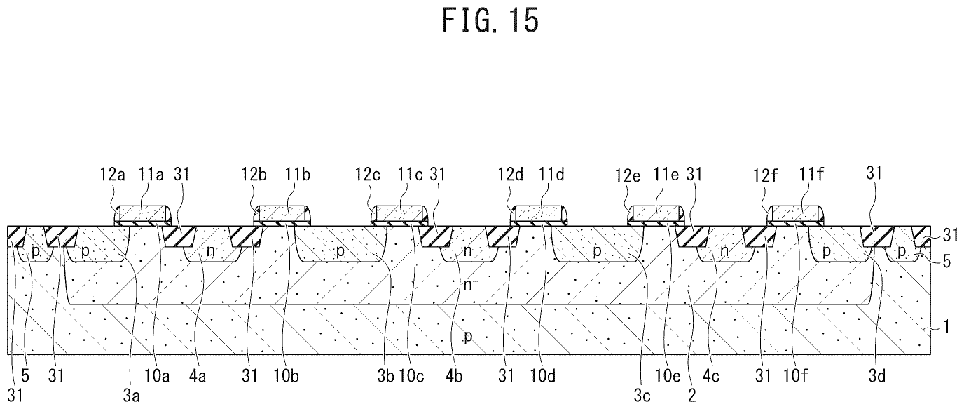

Next, as illustrated in FIG. 14, the element-separation insulating film 31 is formed on the top surface side of the semiconductor base-body 1 by LOCOS, for example. Next, a gate insulating film is formed on the top surface side of the semiconductor base-body 1 by thermal oxidation or chemical vapor deposition (CVD), for example. Further, a polysilicon layer (a doped polysilicon layer) heavily doped with n-type impurities or p-type impurities is provided by CVD using dopant gas. The doped polysilicon layer and the gate insulating film are then partly and selectively removed by photolithography and dry etching so as to form the gate insulating films 10a to 10f and the gate electrodes 11a to 11f (refer to FIG. 15). Subsequently, the side-wall insulating films 12a to 12f are formed on both sides of the respective side surfaces of the gate electrodes 11a to 11f by CVD and dry etching. This step provides the gate electrodes 11a to 11f on the top surface side of the semiconductor base-body 1 with the gate insulating films 10a to 10f interposed, and the side-wall insulating films 12a to 12f are formed on both sides of the respective side surfaces of the gate electrodes 11a to 11f, as illustrated in FIG. 15.

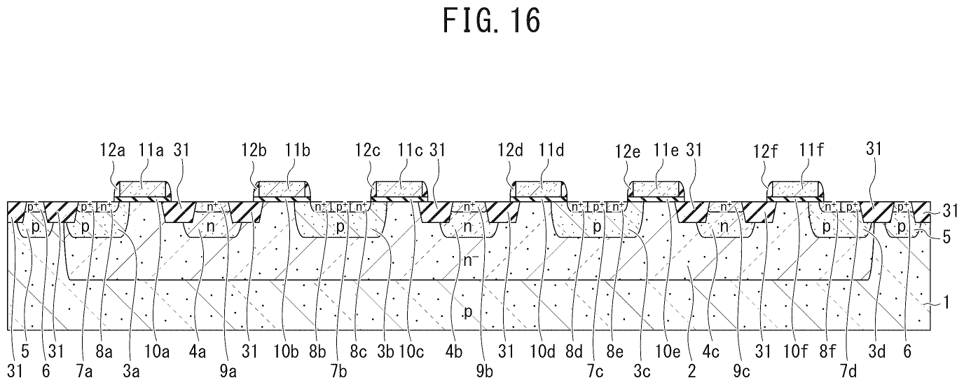

Next, the n⁺-type source regions 8a to 8d and the p⁺-type contact regions 7a to 7d are formed on the top surface side of the channel formation regions 3a to 3d by photolithography, ion implantation, and annealing, as illustrated in FIG. 16. Further, the n⁺-type drain regions 9a to 9c are formed on the top surface side of the drift regions 4a to 4c. Further, the p⁺-type contact region 6 is formed on the top surface side of the well region 5.

Next, the interlayer insulating film 32 is deposited so as to cover the gate electrodes 11a to 11f by CVD, for example. A part of the interlayer insulating film 32 is then selectively removed by photolithography, dry etching, and the like, so as to form contact holes to which the respective top surfaces of the source regions 8a to 8d, the drain regions 9a to 9c, the contact regions 7a to 7d, and the contact region 6 are exposed. Next, the contact holes are filled with a metal film by sputtering, photolithography, and dry etching, for example, so as to form the vias 21a, 22a, 22b, 23a, 24a to 24c, 25a, 26a to 26c, 27a, 28a, 28b, and 29a, the substrate contact electrodes 21 and 29, the source electrodes 22, 24, 26, and 28, and the drain electrodes 23, 25, and 27. Thereafter, the passivation insulating film 33 is formed so as to cover the substrate contact electrodes 21 and 29, the source electrodes 22, 24, 26, and 28, and the drain electrodes 23, 25, and 27. The semiconductor device according to the first embodiment illustrated in FIG. 1 is thus completed.

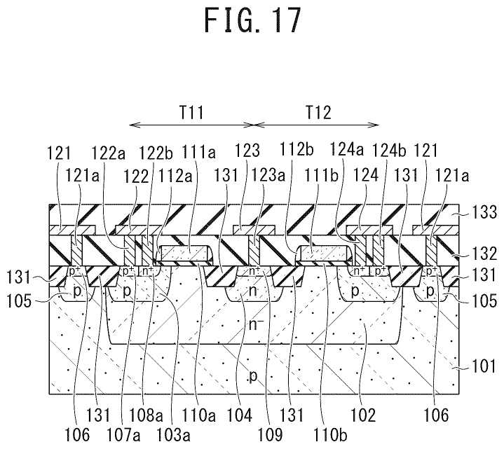

A semiconductor device of a first comparative example is described below. FIG. 17 is a cross-sectional view illustrating the semiconductor device of the first comparative example. As illustrated in FIG. 17, the semiconductor device of the first comparative example differs from the semiconductor device according to the first embodiment illustrated in FIG. 1 in including a lateral MOSFET not having an arrayed structure. The semiconductor device of the first comparative example includes a semiconductor base-body 101 of p-type, and a well region 102 of n-type provided on the top surface side of the semiconductor base-body 101. The semiconductor device of the first comparative example further includes channel formation regions 103a and 103b of p-type on the top surface side of the well region 102.

A contact region 107a of p⁺-type and a source region 108a of n⁺-type are provided on the top surface side of the channel formation region 103a. The contact region 107a is connected to a source electrode 122 through a via 122a penetrating an interlayer insulating film 132. The source region 108a is connected to the source electrode 122 through a via 122b penetrating the interlayer insulating film 132. The source electrode 122 is covered with a passivation insulating film 133.

A drift region 104 of n-type is provided in the middle on the top surface side of the well region 102. A drain region 109 of n⁺-type is provided on the top surface side of the drift region 104. The drain region 109 is connected to a drain electrode 123 through a via 123a penetrating the interlayer insulating film 132. An element-separation insulating film 131 is provided on both sides of the respective side surfaces of the drift region 104 and the drain region 109.

A gate electrode 111a is provided on the respective top surface sides of the channel formation region 103a and the well region 102 with a gate insulating film 110a interposed at a position between the source region 108a and the drain region 109. A side-wall insulating film 112a is provided to cover the side surfaces on both sides of the gate electrode 111a.

A source region 108b of n⁺-type and a contact region 107b of p⁺-type are provided on the top surface side of the channel formation region 103b. The source region 108b is connected to a source electrode 124 through a via 124a penetrating the interlayer insulating film 132. The contact region 107b is connected to the source electrode 124 through a via 124b penetrating an interlayer insulating film 132.

A gate electrode 111b is provided on the respective top surface sides of the channel formation region 103b and the well region 102 with a gate insulating film 110b interposed at a position between the drain region 109 and the source region 108b. A side-wall insulating film 112b is provided to cover the side surfaces on both sides of the gate electrode 111b.

A transistor cell T11 includes the contact region 107a, the source region 108a, the drain region 109, and the gate electrode 111a. A transistor cell T12 has a linear symmetric structure with respect to the transistor cell T11 about the drain region 109. The transistor cell T12 includes the contact region 107b, the source region 108b, the drain region 109, and the gate electrode 111b. The drain region 109 is commonly used in the respective transistor cells T11 and T12.

A well region 105 of p-type is provided on the top surface side of the semiconductor base-body 101 on the outside of the well region 102. A contact region 106 of p⁺-type is provided on the top surface side of the well region 105. The contact region 106 is connected to a substrate contact electrode 121 through a via 121a penetrating the interlayer insulating film 132. The element-separation insulating film 131 is provided on both sides of the respective side surfaces of the well region 105 and the contact region 106.

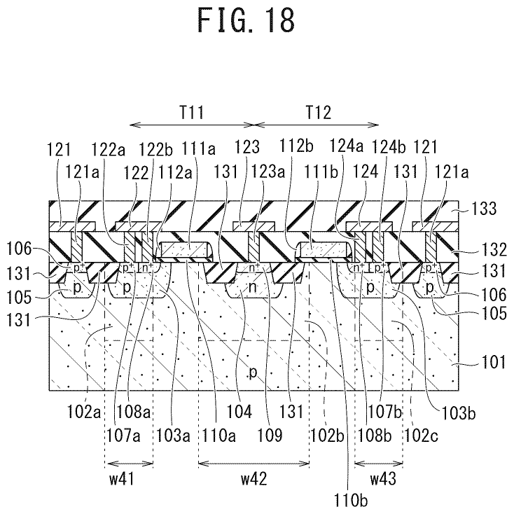

FIG. 18 is a cross-sectional view schematically illustrating, instead of the n-type well region 102 illustrated in FIG. 17, ion implantation regions 102a to 102c for forming the well region 102 during the manufacture of the semiconductor device of the first comparative example. The ion implantation region 102a is formed to have a width w41 so as to overlap with the channel formation region 103a. The ion implantation region 102b is formed to have a width w42 wider than the width w41 so as to overlap with the drift region 104. The ion implantation region 102c is formed to have a width w43 substantially equal to the width w41 so as to overlap with the channel formation region 103b.

As compared with this comparative example, the semiconductor device according to the first embodiment has the configuration, as illustrated in FIG. 6 and FIG. 7, in which the widths w31 and w32 of the ion implantation regions 2c and 2e, among the ion implantation regions 2a to 2f, located at the positions overlapping with the channel formation regions 3b and 3c are narrower than the widths w41 to w43 of the ion implantation regions 102a to 102c in the semiconductor device of the first comparative example. This configuration avoids the sufficient diffusion of the n-type impurities included in the ion implantation regions 2c and 2e in the lateral direction by the annealing, which leads a region having a low impurity concentration to be locally formed in the well region 2.

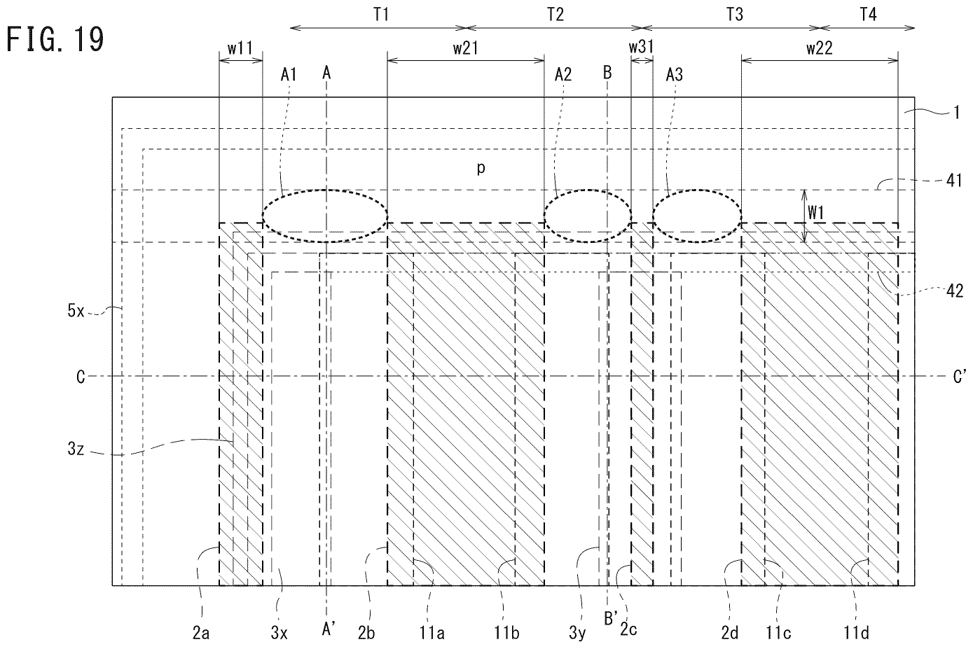

A semiconductor device of a second comparative example is described below. The semiconductor device of the second comparative example has a configuration common to that of the semiconductor device according the first embodiment in including the lateral MOSFET having the arrayed structure. FIG. 19 is a plan view for explaining a method of manufacturing the semiconductor device of the second comparative example, corresponding to the plan view for explaining the method of manufacturing the semiconductor device according to the first embodiment illustrated in FIG. 8A.

The method of manufacturing the semiconductor device of the second comparative example also forms the ion implantation regions 2a to 2d in the ion implantation step for forming the n-type well region 2, but differs from the method of manufacturing the semiconductor device according to the first embodiment illustrated in FIG. 8A in not forming the ion implantation region 2x connected to the ion implantation region 2c, as illustrated in FIG. 19.

FIG. 19 indicates a region A1 by the broken line at a position corresponding to the end part of the gate electrode 11a and the end part of the well region 2 immediately under the wiring layer 41. FIG. 19 also indicates a region A2 by the broken line at a position corresponding to the end part of the gate electrode 11b and the end part of the well region 2 immediately under the wiring layer 41. FIG. 19 also indicates a region A3 by the broken line at a position corresponding to the end part of the gate electrode 11c and the end part of the well region 2 immediately under the wiring layer 41.

The semiconductor device of the second comparative example can lead the n-type impurities to be sufficiently diffused in the lateral direction by the annealing, since the ion implantation regions 2a, 2b, and 2d each have a greater width than the ion implantation region 2c. The impurity concentration at the end part of the well region 2, corresponding to the region A1 indicated by the broken line, between the ion implantation regions 2a and 2b is not decreased, or no channel is formed on the surface of the end part of the well region 2 even immediately under the wiring layer 41.

On the other hand, the ion implantation region 2c, which is narrower than the ion implantation regions 2a, 2b, and 2d, does not lead the n-type impurities to be diffused sufficiently in the lateral direction by the annealing. The impurity concentration at the end part of the well region 2, corresponding to the region A2 indicated by the broken line between the ion implantation regions 2b and 2c, is thus lower than that of the well region 2 at the position corresponding the region A1 indicated by the broken line. Further, the impurity concentration at the end part of the well region 2, corresponding to the region A3 indicated by the broken line between the ion implantation regions 2c and 2d, is also lower than that at the position corresponding the region A1 indicated by the broken line. A channel is thus formed on the surface of the well region 2 at the respective positions with the relatively low impurity concentration corresponding to the regions A2 and A3 indicated by the broken lines if a potential is applied to the wiring layer 41, resulting in a cause of a leakage path.

In contrast, the method of manufacturing the semiconductor device according to the first embodiment includes the ion implantation step for forming the well region 2 that forms the ion implantation region 2x on the end part side of the ion implantation region 2c having the narrower width than the ion implantation regions 2a, 2b, and 2d, as illustrated in FIG. 8A. The impurity concentration at the end part of the well region 2, corresponding to the region A2 indicated by the broken line between the ion implantation regions 2b and 2c, is thus higher than or equal to that of the well region 2 at the position indicated by the region A1. In addition, the impurity concentration at the end part of the well region 2, corresponding to the region A3 indicated by the broken line between the ion implantation regions 2c and 2d, is also higher than or equal to that of the well region 2 at the position indicated by the region A1. The configuration of the semiconductor device according to the first embodiment thus can avoid a formation of a channel on the surface of the well region 2 at the positions indicated by the regions A2 and A3, so as to prevent a cause of a leakage path accordingly.

### SECOND EMBODIMENT

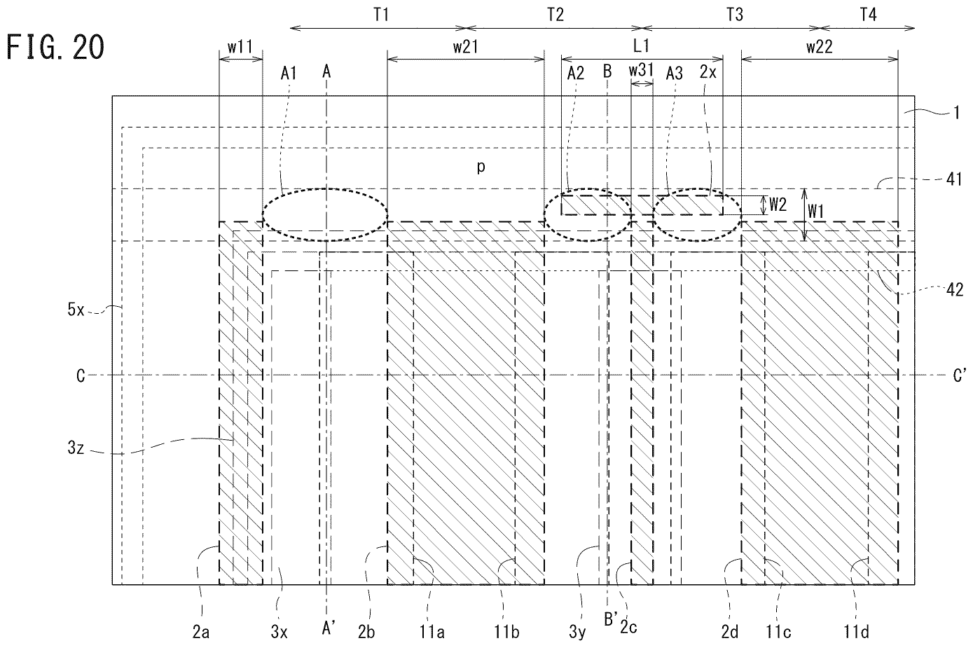

FIG. 20 is a plan view for explaining a method of manufacturing a semiconductor device according to a second embodiment, corresponding to the plan view for explaining the manufacturing method according to the first embodiment illustrated in FIG. 8A. As illustrated in FIG. 20, the method of manufacturing the semiconductor device according to the second embodiment differs from the manufacturing method according to the first embodiment illustrated in FIG. 8A in forming the ion implantation region 2x separately from the ion implantation region 2c in the ion implantation step for forming the n-type well region 2. The other steps of the method of manufacturing the semiconductor device according to the second embodiment are substantially the same as those according to the first embodiment, and overlapping explanations are not repeated below.

The method of manufacturing the semiconductor device according to the second embodiment that provides the ion implantation region 2x, as in the case according to the first embodiment, can also prevent a decrease in the impurity concentration of the well region 2 at the positions corresponding the regions A2 and A3 indicated by the broken lines in FIG. 3 to FIG. 5. The present embodiment thus can avoid a formation of a channel on the surface of the well region 2 at the positions indicated by the regions A2 and A3 if a potential is applied to the wiring layer 41, so as to prevent a cause of a leakage path accordingly.

### THIRD EMBODIMENT

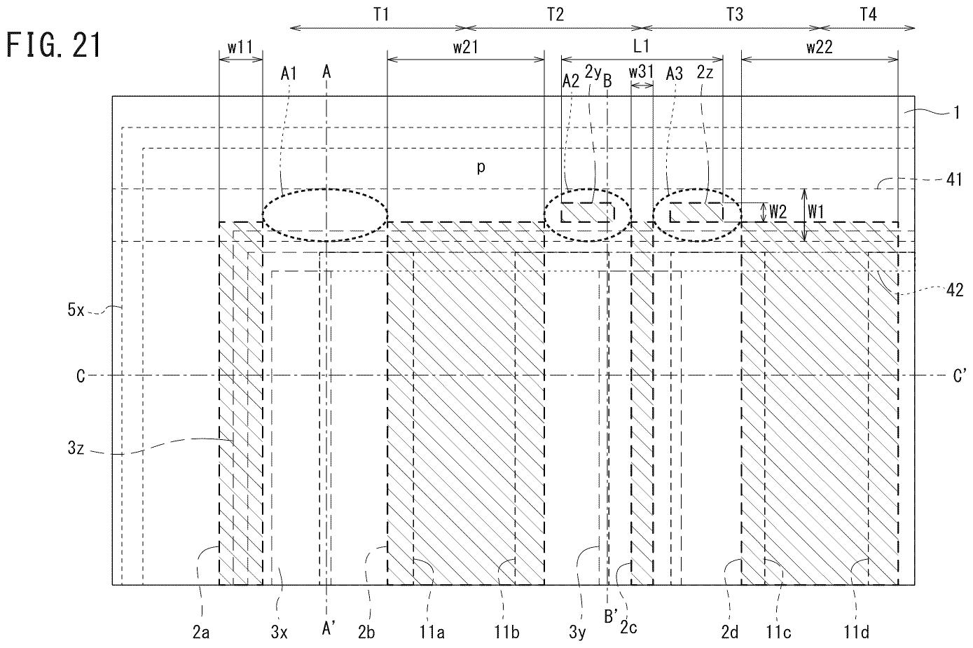

FIG. 21 is a plan view for explaining a method of manufacturing a semiconductor device according to a third embodiment, corresponding to the plan view for explaining the manufacturing method according to the first embodiment illustrated in FIG. 8A. As illustrated in FIG. 21, the method of manufacturing the semiconductor device according to the third embodiment differs from the manufacturing method according to the first embodiment illustrated in FIG. 8 in forming ion implantation regions 2y and 2z separately from the ion implantation region 2c in the ion implantation step for forming the n-type well region 2. The ion implantation regions 2y and 2z are provided separately from each other. The other steps of the method of manufacturing the semiconductor device according to the third embodiment are substantially the same as those according to the first embodiment, and overlapping explanations are not repeated below.

The method of manufacturing the semiconductor device according to the third embodiment, which provides the ion implantation regions 2y and 2z, can also prevent a decrease in the impurity concentration of the well region 2 at the positions corresponding the regions A2 and A3 indicated by the broken lines in FIG. 3 to FIG. 5, as in the case according to the first embodiment. The present embodiment thus can avoid a formation of a channel on the surface of the well region 2 at the positions indicated by the regions A2 and A3 if a potential is applied to the wiring layer 41, so as to prevent a cause of a leakage path accordingly.

### OTHER EMBODIMENTS

As described above, the invention has been described according to the first to third embodiments, but it should not be understood that the description and drawings implementing a portion of this disclosure limit the invention. Various alternative embodiments of the present disclosure, examples, and operational techniques will be apparent to those skilled in the art from this disclosure.

For example, the first to third embodiments each illustrate the method of manufacturing the semiconductor device with the configuration in which the ion implantation regions 2c and 2e located at the positions overlapping with the channel formation regions 3b and 3c have the relatively narrow widths among the ion implantation regions 2a to 2g, as illustrated in FIG. 7, but the present disclosure is not limited to this case. The ion implantation regions 2b, 2d, and 2f overlapping with the drift regions 4a to 4c may each have a relatively narrow width. In such a case, an ion implantation region similar to the ion implantation region 2x as illustrated in FIG. 8A may be formed on the end part side of the respective ion implantation regions 2b, 2d, and 2f with the relatively narrow width.

Further, the semiconductor devices according to the first to third embodiments are illustrated with the lateral MOSFET, but the present disclosure can also be applied to a lateral IGBT.

In addition, the respective configurations disclosed in the first to third embodiments can be combined together as appropriate without contradiction with each other. As described above, the invention includes various embodiments of the present disclosure and the like not described herein. Therefore, the scope of the present disclosure is defined only by the technical features specifying the present disclosure, which are prescribed by claims, the words and terms in the claims shall be reasonably construed from the subject matters recited in the present specification.

What is claimed is:

1. A semiconductor device comprising:
a semiconductor base-body of a first conductivity-type;
a well region of a second conductivity-type provided on a top surface side of the semiconductor base-body;
a plurality of channel formation regions of the first conductivity-type provided on a top surface side of the well region and extending parallel to each other in one direction in a planar view;
a plurality of drift regions provided on the top surface side of the well region alternately with the channel formation regions and extending parallel to each other in the one direction;
a plurality of carrier-supply regions of the second conductivity-type provided on top surface sides of the respective channel formation regions;
a plurality of carrier-reception regions of the second conductivity-type provided on top surface sides of the respective drift regions;
a plurality of gate electrodes provided on top surface sides of the respective channel formation regions with a gate insulating film interposed at positions between the carrier-supply regions and the well region, and extending parallel to each other in the one direction; and
a wiring layer arranged over the well region on an end part side of the channel formation regions and the drift regions in the one direction to extend in a direction perpendicular to the one direction,
wherein an impurity concentration of the well region at a position located on the end part side of the channel formation regions interposed between the drift regions next to each other and overlapping with the wiring layer is greater than or equal to that of the well region at a position on the end part side of the drift regions and overlapping with the wiring layer.

2. The semiconductor device of claim 1, further comprising a plurality of transistor cells, wherein two of the transistor cells each including one of the gate electrodes located next to each other commonly use one of the carrier-supply regions and have a linearly symmetric structure about the common carrier-supply region.

3. The semiconductor device of claim 1, further comprising a plurality of transistor cells, wherein two of the transistor cells each including one of the gate electrodes located next to each other commonly use one of the carrier-reception regions and have a linearly symmetric structure about the common carrier-reception region.

4. A method of manufacturing the semiconductor device according to claim 1, the method comprising forming the well region including:
implanting impurity ions of the second conductivity-type to form a plurality of first ion implantation regions formed into slits extending parallel to the one direction and having different widths, and form a second ion implantation region extending in the direction perpendicular to the one direction at a position overlapping with the wiring layer on an end part side of one of the first ion implantation regions having a relatively narrow width; and
diffusing the impurity ions implanted to the first ion implantation regions and the second ion implantation region in a lateral direction by annealing so as to form the well region.

5. The method of manufacturing the semiconductor device of claim 4, wherein the one of the first ion implantation regions having the relatively narrow width is provided at a position overlapping with one of the channel formation regions interposed between the drift regions next to each other.

6. The method of manufacturing the semiconductor device of claim 4, wherein the second ion implantation region is formed so as to be connected to an end part of the one of the first ion implantation regions having the relatively narrow width.

7. The method of manufacturing the semiconductor device of claim 4, wherein the second ion implantation region is formed separately from the end part of the one of the first ion implantation regions having the relatively narrow width.

8. The method of manufacturing the semiconductor device of claim 4, wherein the step of forming the well region forms a plurality of the second ion implantation regions separately from each other in the direction perpendicular to the one direction.
